(19) United States
(12) Patent Application Publication
(10) Pub. No.: US 2012/0032327 A1
(43) Pub. Date: Feb. 9, 2012

(54) SYSTEMS AND METHODS FOR REINFORCING CHIP PACKAGES

(75) Inventors: Michael G. Lee, Saratoga, CA (US); Chihiro Uchibori, Campbell, CA (US)

(73) Assignee: FUJITSU LIMITED, Kanagawa (JP)

(21) Appl. No.: 12/852,899

(22) Filed: Aug. 9, 2010

(51) Int. Cl. H01L 23/488; H01R 9/00; H01L 21/66

(52) U.S. Cl. 257/738; 438/5; 361/772; 257/E23.023; 257/E21.529

(57) ABSTRACT

In accordance with some embodiments of the present disclosure, a chip package is provided. The chip package may include a chip, a substrate, and an interconnect layer disposed between the chip and the substrate. In some embodiments, the interconnect layer may include an array of bonding interconnects configured to provide electrical communication between the chip and a printed circuit board and reinforcement interconnects arranged around an outermost row of the array of bonding interconnects.

### TECHNICAL FIELD

The present disclosure relates to chip packaging, and in particular, systems and methods for reinforcing chip packaging using reinforcement interconnects.

### BACKGROUND

Chip packaging is used to protect a chip, or die, and provides electrical connections and a thermal path for excess heat. Recently, plastic packages have been used to package chips because plastic packages are relatively low cost compared to conventional ceramic packages. However, plastic packages have a much higher coefficient of thermal expansion (CTE), and may cause certain problems with the chip. For example, when a chip and a plastic package are bonded together, chip package interaction (CPI) can occur when a mismatch in the CTE of the chip and the package gives rise to local stress in the region between the chip and the plastic package, e.g., solder bumps and on-chip interconnects. Warping, delamination, and cracks have been observed near the die corners and peripheral areas, where the distance from the die center is the longest and the cumulative displacement is the largest.

### SUMMARY

In accordance with some embodiments of the present disclosure, a chip package is provided. The chip package may include a chip, a substrate, and an interconnect layer disposed between the chip and the substrate. In some embodiments, the interconnect layer may include an array of bonding interconnects configured to provide electrical communication between the chip and a printed circuit board and reinforcement interconnects arranged around an outermost row of the array of bonding interconnects.

In other embodiments of the present disclosure, an interconnect layer is provided. The interconnect layer may include an array of bonding interconnects configured to provide electrical communication between the chip and a printed circuit board and reinforcement interconnects arranged around an outermost row of the array of bonding interconnects.

In certain embodiments of the present disclosure, a method for reinforcing a chip package is provided. The method may include steps for providing a row of reinforcement interconnects around a portion of an outermost row of a bonding interconnect array, determining a stress on the chip package with the row of reinforcement interconnects, determining if the determined stress exceeds a predetermined stress level, and adjusting the row of reinforcement interconnects if the determined stress exceeds the predetermined stress level.

### BRIEF DESCRIPTION OF THE DRAWINGS

A more complete understanding of the present embodiments and advantages thereof may be acquired by referring to the following description taken in conjunction with the accompanying drawings, in which like reference numbers indicate like features, and wherein:

FIG. 1 illustrates a cut-away view of layers in a chip package that includes reinforcement interconnects, in accordance with certain embodiments of the present disclosure;

FIGS. 2A-2E illustrate a top view of an interconnect layer with reinforcement interconnects, in accordance with certain embodiments of the present disclosure; and

FIG. 3 illustrates a flow chart of example method for arranging reinforcement interconnects, in accordance with certain embodiments of the present disclosure.

### DETAILED DESCRIPTION

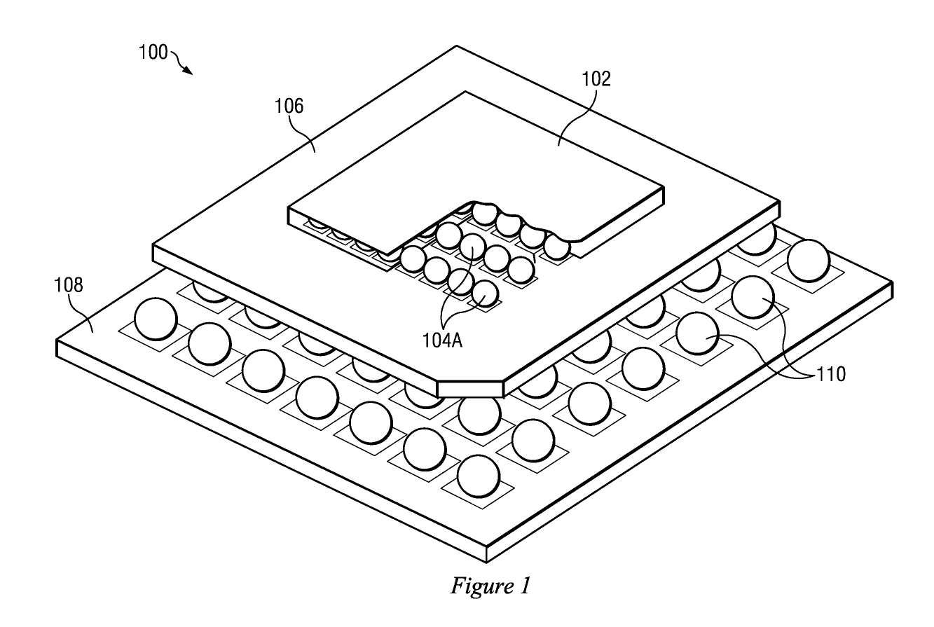

Preferred embodiments and their advantages are best understood by reference to FIGS. 1 through 3, wherein like numbers are used to indicate like and corresponding parts.

FIG. 1 illustrates a cut-away view of layers in a chip package 100 including reinforcement interconnects, in accordance with certain embodiments of the present disclosure. Chip package 100 may be a plastic ball grid array (PBGA) that provides electrical and or mechanical connections for chip 102. Chip package may include chip 102, interconnects 104 and 110, substrate 106, and printed circuit board 108.

Chip 102, also referred to as a die, may be an integrated circuit, a microelectromechanical system (MEMS), or other circuitry. Chip 102 may be mounted to plastic substrate 106 using interconnects 104. For example, using a technique known as “flip chip”, chip 102 may be “flipped over” so that the top side of chip 102 faces down towards substrate 106. Interconnects 104, which may be multiple solder balls arranged in an array, may be heated to complete the mounting process. It is noted that interconnects 104 may be arranged in any suitable fashion. It is also noted that other mounting techniques may also be used to bond chip 102 to substrate 106 (e.g., wire bonding).

Chip 102 and substrate 106 may be communicatively coupled to printed circuit board (PCB) 108. PCB 108 may include a series of copper pads on its surface patterned to match the interconnects 104. Using, for example, a standard mount technology, chip 102 on substrate 106 may be positioned on the copper pads of PCB 108. Interconnects 110, for example solder balls arranged in an array, may be situated on the copper pads, may be solder balls that may be heated to bond chip 102 and substrate 106 to PCB 108.

As noted above, interconnects 104 and interconnects 110 may include solder balls or other metallic substances used to conduct electrical signals from chip 102 to PCB 108. When interconnects 104 are heated, either in a reflow oven or by an infrared heater, the interconnects melt. Surface tension causes the molten solder to hold chip 102 and substrate 106 in alignment with PCB 108, at the correct separation distance, while the interconnects cool and solidify.

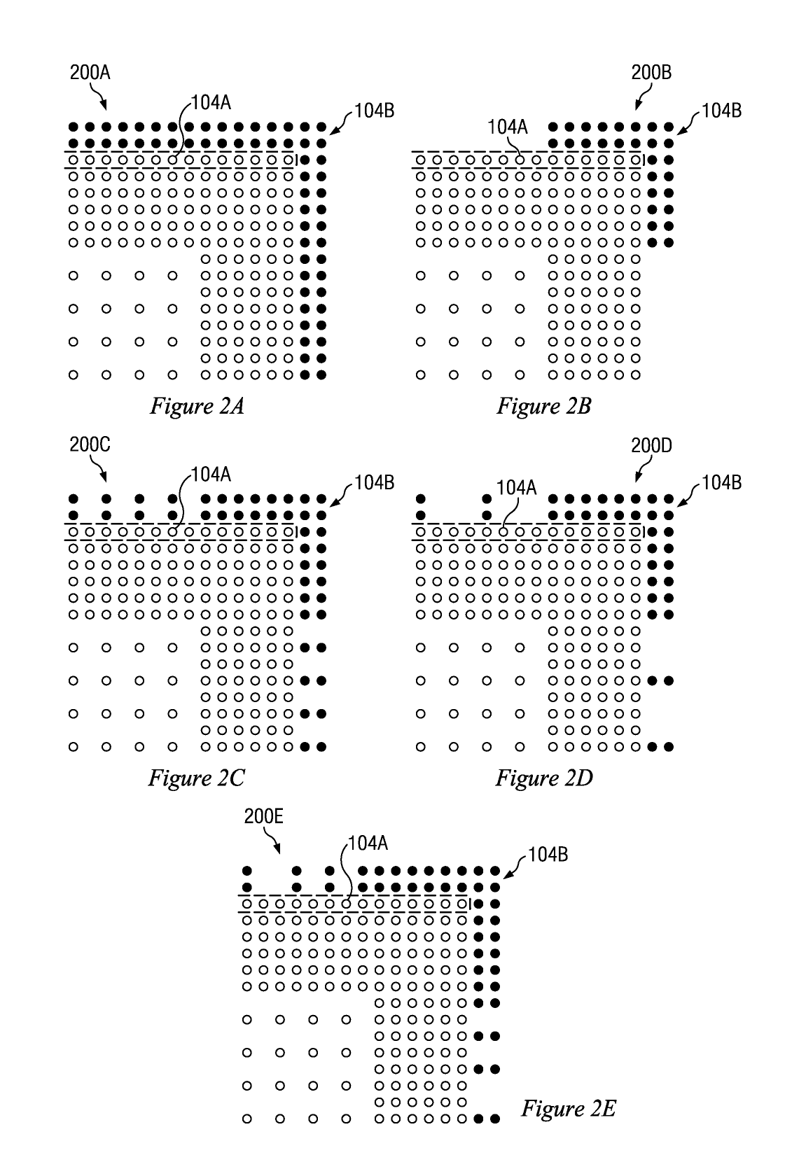

In some embodiments, interconnects 104 may include bonding interconnects and reinforcement interconnects configured to provide stress relief due to, for example, mechanical stress or thermomechanical stress between chip 102 and substrate 106. In some embodiments, the reinforcement interconnects may be made of the same material as the bonding interconnects, although the reinforcement interconnects may not provide electrical functionality. Details of the reinforcement interconnects are described below with respect to FIGS. 2A-2E.

FIG. 2A illustrates a top view of an interconnect layer 200A with reinforcement interconnects, in accordance with certain embodiments of the present disclosure. Interconnect layer 200A may be a layer disposed between chip 102 and substrate 106 and may include interconnects 104. In some embodiments, interconnects 104 may include bonding interconnects 104A and reinforcement interconnects 104B.

Bonding interconnects 104A may include multiple solder balls or solder bumps arranged in an array at any suitable pitch for providing an electrical connection between chip 102 and PCB 108. In some embodiment, bonding interconnects 104A are configured as a ball grid array.

Reinforcement interconnects 104B may be a made of the same material as bonding interconnects 104A and may be configured to reduce and/or substantially eliminate thermomechanical and/or mechanical stress generally seen between chip 102 and plastic substrate 106. For example, reinforcement interconnects 104B may reduce the stress on bonding interconnects 104A, which provide the electrical connection between chip 102 and PCB 108.

As shown in FIG. 2A, two rows of reinforcement interconnections 104B may be arranged around the outermost rows and/or columns of bonding interconnects 104A. While FIG. 2A shows two rows of reinforcement interconnections 104B that fully encompass the outermost edge of bonding interconnects 104A, it is noted that any number of row(s) of reinforcement interconnects 104B may be arranged around the outermost row of bonding interconnects 104A.

In some embodiments, reinforcement interconnects 104B may be arranged around certain portions of the outermost row of bonding interconnects 104A. For example, referring to FIG. 2B, two rows of reinforcing interconnects 104B are situated around corners of layer 200B is shown. The rows of reinforcing interconnects 104B may coincide with the corners of chip 102 when bonded with substrate 106. The corners of layer 200B when bonded with chip 102 may suffer more thermomechanical and/or mechanical stress than other portions of layer 200B, and thus, by introducing one or more rows of reinforcement interconnects 104B, the stress to bonding interconnects 104A may be minimized or substantially eliminated. In the same or alternative embodiments, reinforcement interconnects 104B may be situated at other portions of interconnect layer 200B that coincide with areas that are more prone to defects or increased stress load when chip 102 is bonded with PCB 108. It is noted that the number of rows of reinforcement interconnects 104B may vary at certain portions of interconnect layer 200B. For example, there may be more rows of reinforcement interconnects 104B around the corners of layer 200B compared to other portions. In some embodiments, the number of rows of reinforcement interconnects 104B may be uniform across portions of interconnect layer 200B.

In other embodiments, reinforcement interconnects 104 may be arranged at various pitch and/or spacing. Referring to FIGS. 2C and 2D, example spacings of reinforcement interconnects 104B are shown. In FIG. 2C, reinforcement interconnects 104B may be arranged around a corner of interconnect layer 200C in a 1:1 ratio, meaning that every row and/or column of interconnect layer proximate to a corner may include at least one reinforcement interconnect 104B. In the same or alternative embodiments, reinforcement interconnects 104B may be spaced at a 1:2 ratio about the outermost rows and/or columns of interconnect layer 200C at locations not proximate to a corner, meaning every other row and/or column of interconnect layer 200 may include at least one reinforcement interconnect 104B. Similarly, in FIG. 2D, reinforcement interconnects 104B may be arranged around a corner of interconnect layer 200D and may be spaced at a 1:4 ratio about the outermost rows and/or columns of interconnect layer 200D at locations not proximate to a corner, meaning every fourth row and/or column of interconnect layer 200D may include at least one reinforcement interconnect 104B. It is noted that other spacing ratios, e.g., 1:8 ratio, 1:6 ratio, 2:3 ratio, 3:4 ratio, etc., may also be used depending on the design criteria of chip package 100.

FIGS. 2C and 2D illustrate examples of arranging reinforcement interconnects 104B at a fixed interval across a portion of interconnect layer 200, e.g., a fixed spacing between each of reinforcement interconnects 104B. In some embodiments, the fixed interval spacing may occur around the entire interconnect layer 200. In the same or alternative embodiments, the fixed interval spacing may occur at certain portions of interconnect layer 200. For example, in FIGS. 2C and 2D, the fixed spacing is for portions of interconnect not associated with the corners of interconnect layer 200.

In some embodiments, reinforcement interconnects 104B may be spaced progressively. As shown in FIG. 2E, reinforcement interconnects 104B may be densely arranged around a corner of interconnect layer 200 and progressively spaced across interconnect layer about the outermost rows. In some embodiments, the layout shown in FIG. 2E may allow for improved wiring capabilities while reinforcing areas needed, e.g., corners. In particular, the progressive spacing of reinforcement interconnects 104B may accommodate interconnect “fan out,” where electrical interconnect occur more densely in the center of the chip packaging and less so at the periphery.

In some embodiments, the spacing of reinforcement interconnects 104B may be based at least on a predetermined stress level determined by, for example, a manufacturer of chip package 100. The predetermined stress level may be a value that ensures chip 102 may be coupled to substrate 106 without causing damage (e.g., fracturing of one or more interconnects 104A from thermomechanical stress and/or mechanical stress).

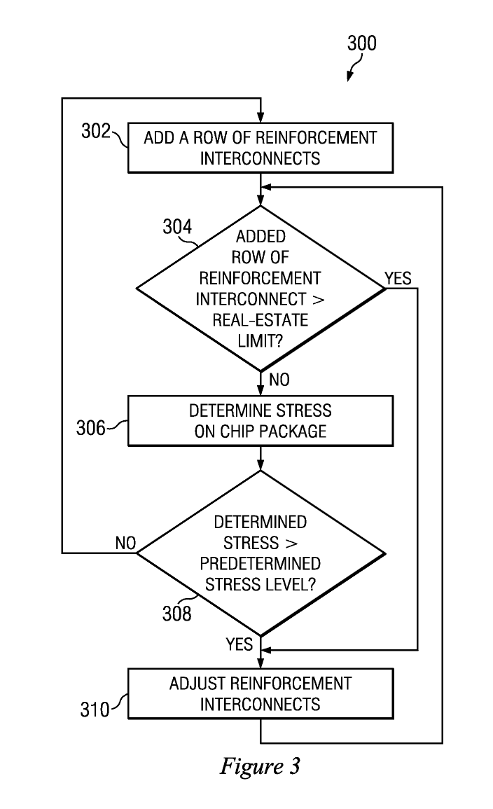

FIG. 3 illustrates a flow chart of example method 300 for arranging reinforcement interconnects on interconnect layer 200, in accordance with certain embodiments of the present disclosure. In some embodiments, method 300 may be implemented using any processing system operable to implement method 300. In certain embodiments, method 300 may be implemented partially or fully in software embodied in tangible computer-readable media. For the purposes of this disclosure, tangible computer-readable media may include any instrumentality or aggregation of instrumentalities that may retain data and/or instructions for a period of time. For example, a tangible computer-readable media may include, without limitation, storage media such as a direct access storage device (e.g., a hard disk drive or floppy disk), a sequential access storage device (e.g., a tape disk drive), compact disk, CD-ROM, DVD, random access memory (RAM), read-only memory (ROM), electrically erasable programmable read-only memory (EEPROM), flash memory, and/or any other suitable media configured to retain data and/or instructions. In some embodiments, chip 100 may be fabricated based at least on the execution of method 300.

In the same or alternative embodiments, chip 100 may be fabricated using the steps of method 300. For example, chip 100 may be a test chip used to determine the number of row(s), the position, and/or the spacing of reinforcement interconnects 104B to reduce and/or substantially eliminate thermomechanical and/or mechanical stress

At step 302, a row of reinforcement interconnects 104B may be arranged around an outermost edge of bonding interconnects 104A. In some embodiments, the row of reinforcement interconnects 104B may be the first row around the outermost row and/or column of bonding interconnects 104A. Alternatively, the row of reinforcement interconnects 104B may be an additional row/column of reinforcement interconnect 104B that surrounds the outermost edge of bonding interconnects 104A.

Reinforcement interconnects 104B may be arranged around portions of interconnect layer 102. For example, reinforcement interconnects 104B may be arranged around a corner of interconnect layer 200, which coincides with a corner edge of chip 102 and substrate 106 when bonded. In the same or alternative embodiments, reinforcement 104B may be arranged around some or all of the outermost edge of bonding interconnects 104A at a fixed or progressive spacing.

At step 304, method 300 may determine if the introduction of the additional reinforcement interconnect row would exceed a real estate limit, a value that may be determined based size of at least chip package 100, chip 102, and/or substrate 106. For example, the number of reinforcement interconnect row(s) cannot exceed the area established when chip 102 is bonded to substrate 106. If the additional row added at step 302 exceeds the real estate limit, method 300 may proceed to step 310. If the additional row added at step 302 does not exceed the real estate limit, method 300 may proceed to step 306.

At step 306, the stress of the chip package with the added reinforcement interconnects 104B is determined. For example, tests such as accelerated thermal cycling (ATC), vibration, thermal shock, and/or highly accelerated stress test (HAST) may be used to determine the stress on chip package 100.

At step 308, method 300 may determine if the determined stress on chip package 100 exceeds the predetermined stress level. If the determined stress on chip package 100 does not exceed the predetermined stress level, method 300 may proceed to step 302 to add further reinforcement interconnects 104B (if needed). If the determined stress on chip package 100 does exceed the predetermined stress level, method 300 may proceed to step 310.

At step 310, reinforcement interconnections 104B may be adjusted to lower the stress on chip package 100 to below the predetermined stress level and/or to fit within the real estate limit. In some embodiments, the number of reinforcement interconnect rows may be altered. For example, if the real estate limit was exceeded at step 304, at least one reinforcement interconnect row may be removed. As another example, if the determined stress is greater than the predetermined stress level, one or more rows of reinforcement interconnect 104B may be added.

In the same or alternative embodiments, adjusting reinforcement interconnects 104B may include adjusting the spacing of reinforcement interconnects 104B. For example, in situation where an additional row of reinforcement interconnects 104B is not allowed, e.g., due to real estate limitation, the spacing of reinforcement interconnects 104B may be altered. As an example, the spacing of reinforcement interconnects 104B may be changed from a fixed spacing to a progressive spacing. Alternatively, the spacing of reinforcement interconnects 104B may be changed from, for example, a 1:4 ratio (as shown in FIG. 2D) to a 1:1 ratio (as shown in FIG. 2A) or other suitable ratio.

In the same or alternative embodiments, adjusting reinforcement interconnects 104B may include rearranging reinforcement interconnects 104B. For example, reinforcement interconnects 104B may be placed in areas that have undergo stresses observed at step 306.

Once the adjustments are made to reinforcement interconnects 104B, method 300 may subsequently proceed to step 304 to determine if the adjustment exceeds the real estate limit and further stress tests may be performed (step 306) to determine if the adjustment(s) improve and/or reduce the stress on chip package 100.

The system and method of the present disclosure may improve yield by reducing the stress on bonding interconnects 104A by adding reinforcement interconnects 104B. The reinforcement interconnects may be manufactured using the standard processes and materials available in the industry. For example, the reinforcement interconnects can be made at the same steps as the bonding interconnects without adding any extra fabrication steps.

Although the present disclosure has been described in detail, it should be understood that various changes, substitutions, and alterations may be made hereto without departing from the spirit and the scope of the invention as defined by the appended claims.

What is claimed is:

1. A chip package, comprising:
a chip;
a substrate;
an interconnect layer disposed between the chip and the substrate, the interconnect layer comprising:
an array of bonding interconnects configured to provide electrical communication between the chip and a printed circuit board; and
reinforcement interconnects arranged around an outermost row of the array of bonding interconnects.

2. The chip package of claim 1, wherein the reinforcement interconnects are configured around the corners of the outermost row of the array of bonding interconnects.

3. The chip package of claim 1, wherein the reinforcement interconnects are arranged in a row around the outermost row of the array of bonding interconnects.

4. The chip package of claim 3, wherein the reinforcement interconnects arranged in the row are arranged around a portion of the outermost row of the array of bonding interconnects at a fixed spacing.

5. The chip package of claim 3, wherein the reinforcement interconnects arranged in the row are arranged around a portion of the outermost row of the array of bonding interconnects at a progressive spacing that increases as the distance from a corner of the array of bonding interconnects increases.

6. The chip package of claim 1, wherein the reinforcement interconnects do not provide electrical communication between the chip and the printed circuit board.

7. The chip package of claim 1, wherein the array of bonding interconnects is a ball grid array.

8. The chip package of claim 1, wherein the bonding interconnects and the reinforcement interconnects comprise solder balls.

9. An interconnect layer, comprising:
an array of bonding interconnects configured to provide electrical communication between a chip and a printed circuit board; and
reinforcement interconnects arranged around an outermost row of the array of bonding interconnects.

10. The interconnect layer of claim 9, wherein the reinforcement interconnects are configured around the corners of the outermost row of the array of bonding interconnects.

11. The interconnect layer of claim 9, wherein the reinforcement interconnects are arranged in a row around the outermost row of the array of bonding interconnects.

12. The interconnect layer of claim 11, wherein the reinforcement interconnects arranged in the row are arranged around a portion of the outermost row of the array of bonding interconnects at a fixed spacing.

13. The interconnect layer of claim 11, wherein the reinforcement interconnects arranged in the row are arranged around a portion of the outermost row of the array of bonding interconnects at a progressive spacing that increases as the distance from a corner of the array of bonding interconnects increases.

14. The interconnect layer of claim 9, wherein the reinforcement interconnects do not provide electrical communication between the chip and the printed circuit board.

15. The interconnect layer of claim 9, wherein the array of bonding interconnects is a ball grid array.

16. The interconnect layer of claim 9, wherein the bonding interconnects and the reinforcement interconnects comprise solder balls.

17. A method for reinforcing a chip package, the method comprising:
providing a row of reinforcement interconnects around a portion of an outermost row of a bonding interconnect array;
determining a stress on the chip package with the row of reinforcement interconnects;
determining if the determined stress exceeds a predetermined stress level; and
adjusting the row of reinforcement interconnects if the determined stress exceeds the predetermined stress level.

18. The method of claim 17, further comprising:
determining if the provided row of reinforcement interconnects exceeds a real estate threshold; and
adjusting the row of reinforcement interconnect if the provided row of reinforcement exceeds the real estate threshold.

19. The method of claim 17, wherein adjusting the row of reinforcement interconnects comprises at least one of:
adjusting a spacing of the reinforcement interconnects in the row; and
adjusting a placement of the row around the outermost row of the bonding interconnects array.

20. The method of claim 17, wherein providing a row of reinforcement interconnects around a portion of an outermost row of a bonding interconnect array comprises providing the row of reinforcement interconnects around a corner of the bonding interconnect array.

21. The method of claim 17, wherein providing a row of reinforcement interconnects around a portion of an outermost row of a bonding interconnect array comprises providing a row of reinforcement interconnects at a progressive spacing that increases as the distance from a corner of the array of bonding interconnects increases.

22. The method of claim 17, wherein providing a row of reinforcement interconnects around a portion of an outermost row of a bonding interconnect array comprises providing a row of reinforcement interconnects at a fixed spacing.
